(19) United States
(12) Patent Application Publication
(10) Pub. No.: US 2024/0120363 A1
(43) Pub. Date: Apr. 11, 2024

(54) PIXEL SENSOR ISOLATION STRUCTURES AND METHODS OF FORMING THE SAME

(71) Applicant: Taiwan Semiconductor Manufacturing Company, Ltd., Hsinchu (TW)

(72) Inventors: Ming-Chyi LIU, Hsinchu City (TW); Jiech-Fun LU, Taiwan (TW); Shih-Chang LIU, Alian Township (TW); Ru-Liang LEE, Hsinchu City (TW)

(21) Appl. No.: 18/150,362

(22) Filed: Jan. 5, 2023

Related U.S. Application Data
(60) Provisional application No. 63/378,736, filed on Oct. 7, 2022.

(51) Int. Cl. H01L 27/146

(52) U.S. Cl. CPC H01L 27/1463; H01L 27/14643; H01L 27/14689

(57) ABSTRACT

A self-aligned plug may be formed between deep trench isolation (DTI) etching cycles. Accordingly, etch depth in areas of a pixel sensor with large CDs (e.g., at an X-road) is reduced, which prevents trench loading. As a result, a floating diffusion (FD) region, associated with photodiodes of the pixel sensor, is not damaged during the DTI etching cycles. Reduced chances of damage to the FD region improves performance of the pixel sensor and prevents electrical shorts and failures, which increases yield and conserves time and raw materials used in forming the pixel sensor.

### CROSS-REFERENCE TO RELATED APPLICATION

This patent application claims priority to U.S. Provisional Patent Application No. 63/378,736, filed on Oct. 7, 2022, entitled “PIXEL SENSOR ISOLATION STRUCTURES AND METHODS OF FORMING THE SAME,” which is hereby expressly incorporated by reference herein.

### BACKGROUND

A complementary metal oxide semiconductor (CMOS) image sensor may include a plurality of pixel sensors. A pixel sensor of the CMOS image sensor may include a transfer transistor, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example pixel array described herein.

FIGS. 3A and 3B are diagrams of examples of a pixel sensor described herein.

FIGS. 4A-4C are diagrams of an example implementation described herein.

FIGS. 5A-5K are diagrams of an example implementation described herein.

FIG. 6 is a diagram of example components of one or more devices of FIG. 1 described herein.

FIG. 7 is a flowchart of an example process associated with forming a semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Photodiodes are often separated by trench isolation structures. For example, back-side deep trench isolation (BDTI) structures may electrically and/or optically isolate photodiode regions. However, an etch rate for etching BDTI structures at an X-road (or a cross-road) generally may be greater relative to other areas of the BDTI structures due to increased critical dimensions (CDs) between the photodiode regions. As used herein, “X-road” refers to a location that is between at least four (e.g., four for a 4T metal oxide semiconductor (CMOS) image sensor or more than four for a 5T CMOS image sensor or a 6T CMOS image sensor) of a plurality of photodiode regions. The increased CDs results from greater diagonal spacing at the X-road between photodiode regions relative to lateral spacing between photodiode regions. Increased CDs results in increase trench depth loading. In particular, the etch rate for etching a trench of a BDTI structure may be greater at the X-road than in other regions of the trench due to the increased CD at the X-road. In some cases, a plasma etch may be performed to etch the trench, in which ions in a plasma are used to bombard the trench to remove material to perform the etch. Radicals in the plasma may more easily diffuse into the trench sidewalls and bottom surface due to the increased CD at the X-road, thereby resulting in a greater etch rate and a greater etch depth at the X-road than the other regions of the trench. Accordingly, if a floating diffusion (FD) region associated with a drain for the photodiode regions is located at or near an X-road of the BDTI structure, the FD region may be damaged during etching because of the increased trench depth loading that occurs when the BDTI structures are formed using multiple etching cycles.

Some implementations described herein provide techniques and apparatuses for forming a self-aligned plug layer between BDTI etching cycles. The self-aligned plug layer is used to protect an X-road between photodiodes when etching a trench for a BDTI structure. The self-aligned plug layer enables other areas of the trench to be etched in additional BDTI etching cycles while the X-road is protected. Accordingly, etch depth in areas with large CDs (e.g., at the X-road) is reduced, which prevents trench loading. As a result, an FD region associated with the photodiode regions is not damaged during the BDTI etching cycles. Reduced chances of damage to the FD region improves performance of an image sensor and prevents electrical shorts and failures, which increases yield and conserves time and raw materials used in forming the image sensor. In some implementations, an etch stop layer (ESL) is deposited over a masking layer (also referred to as a “blocking layer”) to prevent etching to the masking layer when the self-aligned plug layer is etched back.

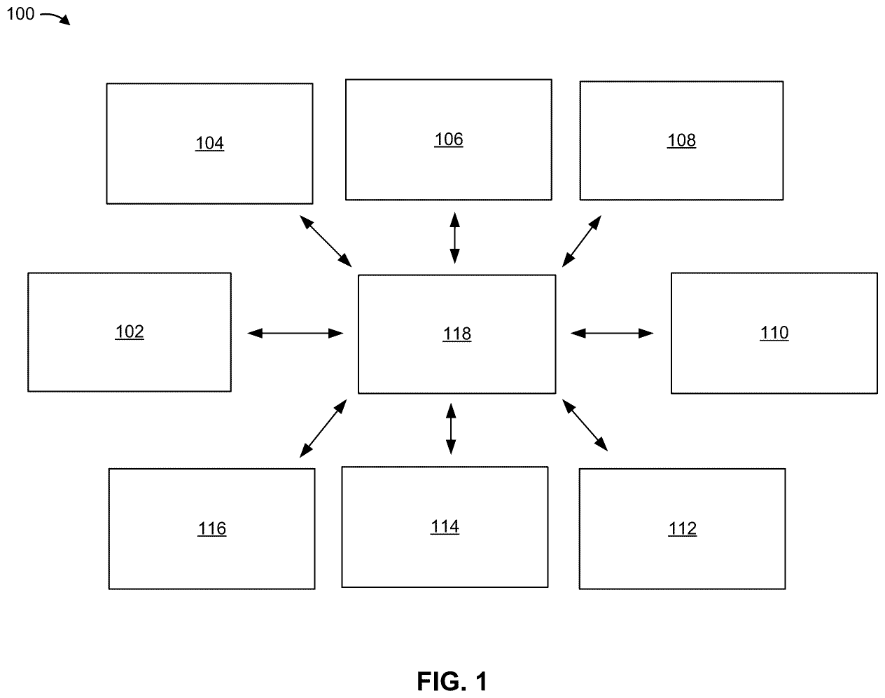

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, an ion implantation tool 114, an annealing tool 116, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, an epitaxy tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The annealing tool 116 is a semiconductor processing tool that includes a semiconductor processing chamber and one or more devices capable of heating a semiconductor substrate or semiconductor device. For example, the annealing tool 116 may include a rapid thermal annealing (RTA) tool or another type of annealing tool that is capable of heating a semiconductor substrate to cause a reaction between two or more materials or gasses, to cause a material to decompose. As another example, the annealing tool 116 may be configured to heat (e.g., raise or elevate the temperature of) a structure or a layer (or portions thereof) to re-flow the structure or the layer, or to crystallize the structure or the layer, to remove defects such as voids or seams. As another example, the annealing tool 116 may be configured to heat (e.g., raise or elevate the temperature of) a layer (or portions thereof) to enable bonding of two or more semiconductor devices.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-116 and/or the wafer/die transport tool 118 may perform one or more semiconductor processing operations described herein. For example, one or more of the semiconductor processing tools 102-116 and/or the wafer/die transport tool 118 may perform a first etch process to form a portion of a trench, for a deep trench isolation (DTI) structure, between a plurality of photodiodes; may form a plug, in the portion of the trench, that includes comprises an organic compound; may perform a second etch process to remove a portion of the plug; and/or may perform a third etch process to form a remainder of the trench for the DTI structure, among other examples.

As another example, one or more of the semiconductor processing tools 102-116 and/or the wafer/die transport tool 118 may form one or more masking layers over a substrate over a plurality of photodiodes; may form a photoresist layer over the one or more masking layers; may etch a portion of a trench using the photoresist layer; may form a plug, in the portion of the trench, that includes an organic compound; may remove a portion of the plug such that a remainder of the plug is in the portion of the trench that is located between four corners of a subset of the plurality of photodiodes; may etch a remainder of the trench using the one or more masking layers; and/or may form a DTI structure in the trench, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

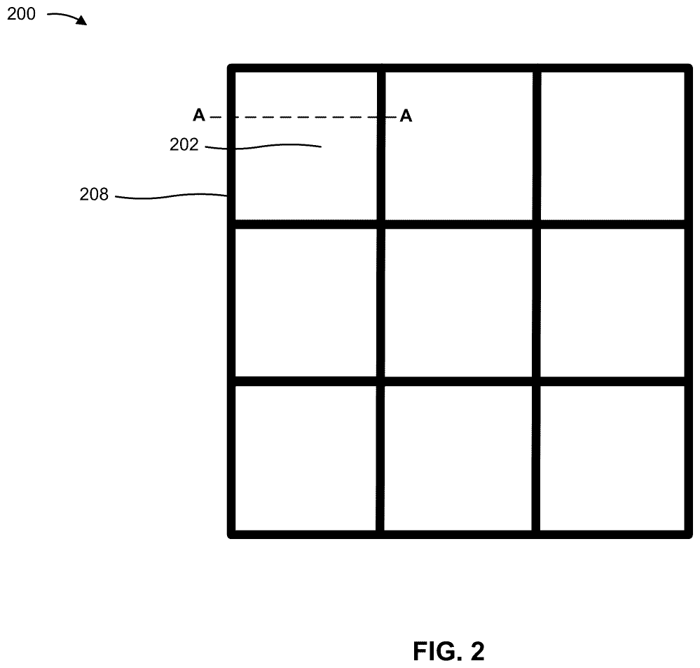

FIG. 2 is a diagram of an example pixel array 200. FIG. 2 illustrates a top-down view of the pixel array 200. In some implementations, the pixel array 200 may be included in an image sensor. The image sensor may include a CMOS image sensor, a backside illuminated (BSI) CMOS image sensor, a front side illuminated (FSI) CMOS image sensor, or another type of image sensor. As shown in FIG. 2, the pixel array 200 may include a plurality of pixel sensors 202. As further shown in FIG. 2, the pixel sensors 202 may be arranged in a grid. In some implementations, the pixel sensors 202 are square-shaped (as shown in the example in FIG. 2). In some implementations, the pixel sensors 202 include other shapes such as rectangle shapes, circle shapes, octagon shapes, diamond shapes, and/or other shapes.

The pixel sensors 202 may be configured to sense and/or accumulate incident light (e.g., light directed toward the pixel array 200). For example, a pixel sensor 202 may absorb and accumulate photons of the incident light in a photodiode. The accumulation of photons in the photodiode may generate a charge representing the intensity or brightness of the incident light (e.g., a greater amount of charge may correspond to a greater intensity or brightness, and a lower amount of charge may correspond to a lower intensity or brightness).

In some implementations, the size of the pixel sensors 202 (e.g., the width or the diameter) of the pixel sensors 202 is in a range from approximately 0.5 micron to approximately 2 microns. In some implementations, the size of the pixel sensors 202 (e.g., the width or the diameter) of the pixel sensors 202 is less than approximately 1 micron. In these examples, the pixel sensors 202 may be referred to as sub-micron pixel sensors. Sub-micron pixel sensors may decrease the pixel sensor pitch (e.g., the distance between adjacent pixel sensors) in the pixel array 200, which may enable increased pixel sensor density in the pixel array 200 (which can increase the performance of the pixel array 200).

The pixel sensors 202 may be electrically and optically isolated by a DTI structure 208 included in the pixel array 200. The DTI structure 208 may include a plurality of interconnected trenches that are filled with a dielectric material such as an oxide. The trenches of the DTI structure 208 may be included around the perimeters of the pixel sensors 202 such that the DTI structure 208 surrounds the pixel sensors 202 (and the photodiodes and drain regions included therein), as shown in FIG. 2. Moreover, the trenches of the DTI structure 208 may extend into a substrate in which the pixel sensors 202 are formed to surround the photodiodes and other structures of the pixel sensors 202 in the substrate. As indicated above, the pixel array 200 may be included in a BSI CMOS image sensor. In these examples, the DTI structure 208 may include a backside DTI (BDTI or BSDTI) structure with a high aspect ratio that is formed from the backside of the pixel array 200.

The pixel array 200 may be electrically connected to a back-end-of-line (BEOL) metallization stack (not shown) of the image sensor. The BEOL metallization stack may electrically connect the pixel array 200 to control circuitry that may be used to measure the accumulation of incident light in the pixel sensors 202 and convert the measurements to an electrical signal. For a BSI CMOS image sensor, the transistor layer may be located between the BEOL metallization stack layers and a lens layer. For a FSI CMOS image sensor, the BEOL metallization stack layers may be located between the transistor layer and the lens layer.

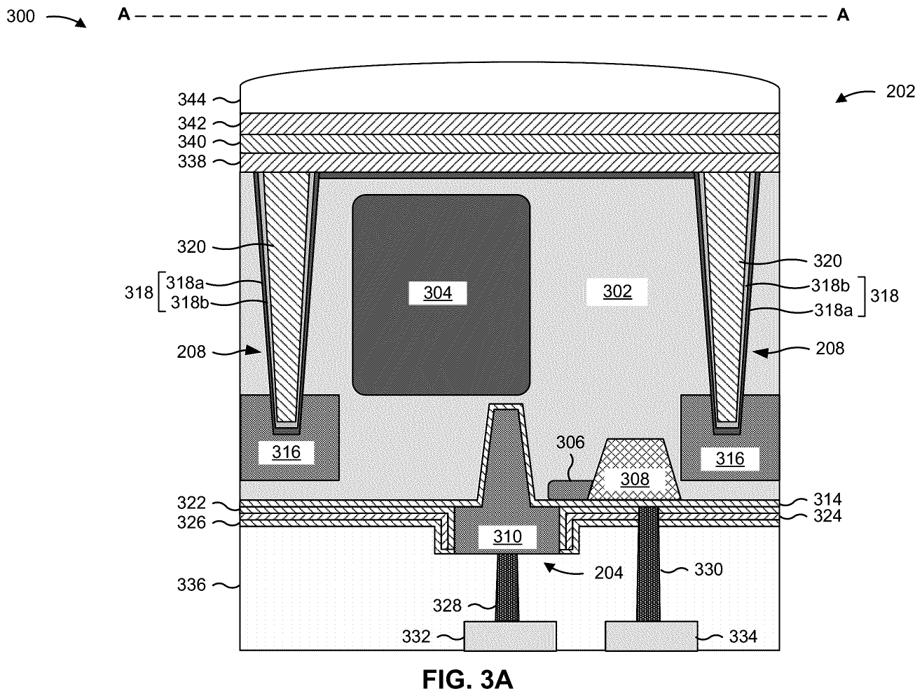

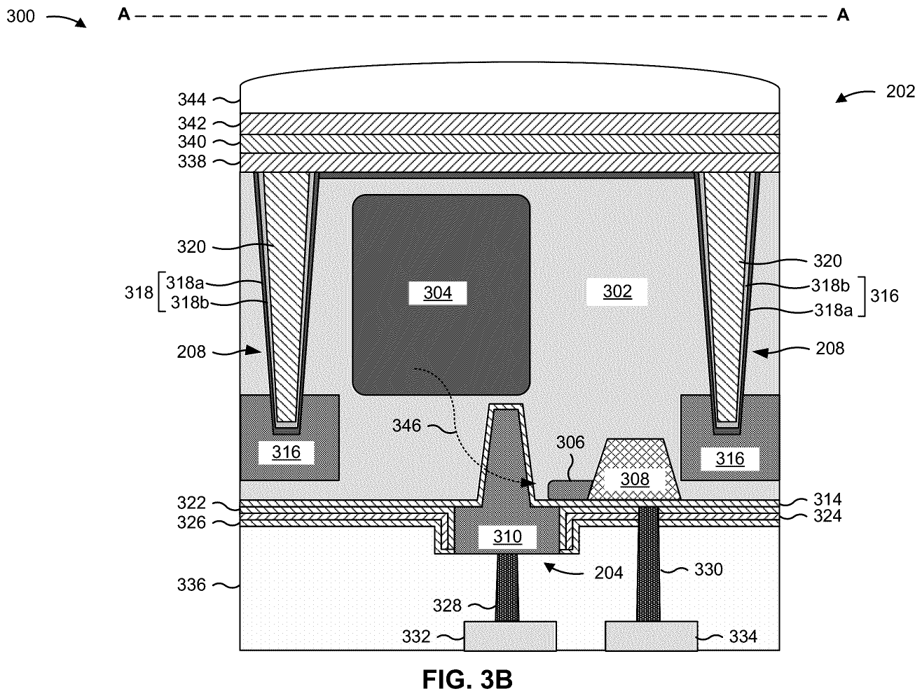

FIG. 2 further illustrates a reference cross-section A-A that is used in one or more figures described herein, such as one or more of FIGS. 3A and 3B. Cross-section A-A is in a plane across a pixel sensor 202 of the pixel array 200. Subsequent figures refer to this reference cross-section for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

FIGS. 3A and 3B are diagrams of example implementation 300 of a pixel sensor 202 described herein. FIGS. 3A and 3B illustrate the example implementation 300 of the pixel sensor 202 in cross-section views of the pixel sensor 202 along the cross-section A-A of the pixel array 200 in FIGS. 2A and 2B. In some implementations, the pixel sensor 202 may be included in the pixel array 200. In some implementations, the pixel sensor 202 may be included in an image sensor. The image sensor may be a CMOS image sensor, a BSI CMOS image sensor, or another type of image sensor.

As shown in FIG. 3A, the pixel sensor 202 may include a substrate 302. The substrate 302 may include a semiconductor die substrate, a semiconductor wafer, a stacked semiconductor wafer, or another type of substrate in which semiconductor pixels may be formed. In some implementations, the substrate 302 is formed of silicon (Si) (e.g., a silicon substrate), a material including silicon, a III-V compound semiconductor material such as gallium arsenide (GaAs), a silicon on insulator (SOI), or another type of semiconductor material that is capable of generating a charge from photons of incident light. In some implementations, the substrate 302 is formed of a doped material (e.g., a p-doped material or an n-doped material) such as a doped silicon.

The pixel sensor 202 may include a photodiode 304 that is included in the substrate 302. The photodiode 304 may include a plurality of regions that are doped with various types of ions to form a p-n junction or a PIN junction (e.g., a junction between a p-type portion, an intrinsic (or undoped) type portion, and an n-type portion). For example, the substrate 302 may be doped with an n-type dopant to form one or more n-type regions of the photodiode 304, and the substrate 302 may be doped with a p-type dopant to form a p-type region of the photodiode 304. The photodiode 304 may be configured to absorb photons of incident light. The absorption of photons causes the photodiode 304 to accumulate a charge (referred to as a photocurrent) due to the photoelectric effect. Photons may bombard the photodiode 304, which causes emission of electrons in the photodiode 304.

The regions included in the photodiode 304 may be stacked and/or vertically arranged. For example, the p-type region may be included over the one or more n-type regions. The p-type region may provide noise isolation for the one or more n-type regions and may facilitate photocurrent generation in the photodiode 304. In some implementations, the p-type region (and thus, the photodiode 304) is spaced away (e.g., downward) from a surface of the substrate 302 to provide noise isolation and/or light-leakage isolation from one or more metallization layers of the pixel sensor 202. The gap between the surface of the substrate 302 and the p-type region may decrease charging of the pixel sensor 202, may decrease the likelihood of plasma damage to the photodiode 304, and/or may reduce the dark current of the pixel sensor 202 and/or the white pixel performance of the pixel sensor 202, among other examples.

The pixel sensor 202 may include a drain extension region 306 and a drain region 308 coupled and/or electrically connected to the drain extension region 306. The drain extension region 306 may be adjacent to the drain region 308. The drain region 308 may include a highly-doped n-type region (e.g., an n⁺ doped region). The drain extension region 306 may include lightly-doped n-type region(s) that facilitate the transfer of photocurrent from the photodiode 304 to the drain region 308. In some implementations, the drain extension region 306 is spaced away (e.g., downward) from a surface of the substrate 302 to provide noise isolation and/or light-leakage isolation from one or more metallization layers of the pixel sensor 202. The gap between the surface of the substrate 302 and the drain extension region 306 may increase noise isolation for the drain extension region 306, may decrease random noise and/or random telegraph noise in the pixel sensor 202, may decrease the likelihood of plasma damage to the drain extension region 306, and/or may reduce the dark current of the pixel sensor 202 and/or the white pixel performance of the pixel sensor 202, among other examples.

The pixel sensor 202 may include a vertical transfer gate (VTG) 204 to control the transfer of photocurrent between the photodiode 304 and the drain region 308. The vertical transfer gate 204 may be energized by applying a voltage or a current to a gate electrode 310 of the vertical transfer gate 204 to cause a conductive channel to form between the photodiode 304 and the drain extension region 306. The conductive channel may be removed or closed by de-energizing the gate electrode 310 of the vertical transfer gate 204, which blocks and/or prevents the flow of photocurrent between the photodiode 304 and the drain region 308.

The vertical transfer gate 204 may be located below and/or under the photodiode 304, which may reduce the lateral width of the pixel sensor 202 as opposed to locating the photodiode 304 side-by-side with the vertical transfer gate 204. The vertical transfer gate 204 extends into the substrate 302 from a surface of the substrate 302 and is adjacent to the drain extension region 306 and the drain region 308. The vertical transfer gate 204 extending into the substrate 302 increases the depth of the conductive channel that is controlled by the vertical transfer gate 204. The increased depth of the conductive channel enables the photodiode 304 to be located deeper in the pixel sensor 202 and closer to where light enters the pixel sensor 202. This may increase the sensitivity and efficiency of the pixel sensor 202.

The gate electrode 310 may include polysilicon, doped polysilicon (e.g., n-doped polysilicon), a metal gate stack, and/or another suitable material. The gate electrode 310 may include a gate electrode stack that includes an n-doped upper transfer gate electrode region and a lower transfer gate electrode region.

A gate dielectric layer 314 may be included between the gate electrode 310 and the substrate 302 of the pixel sensor 202. The gate electrode 310 may be included over and/or on the gate dielectric layer 314. The gate dielectric layer 314 may also extend along a frontside surface of the substrate 302. The gate dielectric layer 314 may include a dielectric material such as tetraethyl orthosilicate (TEOS) or another type of dielectric material.

The pixel sensor 202 may include a plurality of regions to provide electrical isolation and/or optical isolation between the pixel sensor 202 and adjacent pixel sensors. The pixel sensor 202 may include a deep p-well region (DPW) 316 adjacent to, and at least partially surrounding, the photodiode 304. In some implementations, the pixel sensor 202 further includes a cell p-well region (CPW) above the deep p-well region 316. The deep p-well region 316 (and the cell p-well region, if included) may include a circle or ring shape in a top-down view in the substrate 302. The deep p-well region 316 (and the cell p-well region, if included) may each include a p⁺ doped silicon material or another p⁺ doped material.

The DTI structure 208 may be included in the substrate 302 adjacent to the photodiode 304 and the drain region 308. Moreover, the DTI structure 208 may be included above and/or partially in the deep p-well region 316. In some implementations, the DTI structure 208 may be included in a cell p-well region. The DTI structure 208 may include one or more trenches that extend downward into the substrate 302 (e.g., from the backside of the substrate 302), and that are that are adjacent the photodiode 304, the drain extension region 306, and the drain region 308. In a top-down view of the pixel sensor 202, the DTI structure 208 may surround the photodiode 304, the drain extension region 306, and the drain region 308. In other words, the photodiode 304, the drain extension region 306, and the drain region 308 may be included within a perimeter of the DTI structure 208 of the pixel sensor 202. In some implementations, the drain region 308 (or a portion thereof) is located under the DTI structure 208 at an X-road between adjacent pixel sensors 202. The DTI structure 208 may provide optical isolation between the pixel sensor 202 and one or more adjacent pixel sensors to reduce the amount of optical crosstalk between the pixel sensor 202 and the one or more adjacent pixel sensors. In particular, the DTI structure 208 may absorb, refract, and/or reflect photons of incident light, which may reduce the amount of incident light that travels through a pixel sensor 202 into an adjacent pixel sensor and is absorbed by the adjacent pixel sensor.

The DTI structure 208 may include one or more layers 318 between the substrate 302 of the pixel sensor 202 and an oxide layer 320 of the DTI structure 208. The one or more layers 318 may include a passivation layer 318a and a capping layer 318b, among other examples. The passivation layer 318a may be included between the substrate 302 (e.g., the silicon substrate) of the pixel sensor 202 and the capping layer 318b. The capping layer 318b may be included between the passivation layer 318a and the oxide layer 320.

The passivation layer 318a may include a boron (B) material, an amorphous boron (a-B) material, and/or another material. The capping layer 318b may include a silicon (Si) material, an amorphous silicon (a-Si) material, and/or another material. The passivation layer 318a may be included to further decrease optical crosstalk by providing a boron-silicon interface between the passivation layer 318a and the substrate 302. The boron-silicon interface resists, reduces, and/or minimizes penetration and/or diffusion of photons into the sidewall oxide layer 322. The capping layer 318b may be included to protect the passivation layer 318a from damage during one or more semiconductor processing operations for forming the pixel sensor 202. The passivation layer 318a (e.g., an amorphous boron layer) may be included on the back side of the pixel sensor 202 (e.g., on the back side of the substrate), as shown in the example in FIG. 3A.

The oxide layer 320 may function to reflect incident light toward the photodiode 304 to increase the quantum efficiency of the pixel sensor 202 and to reduce optical crosstalk between the pixel sensor 202 and one or more adjacent pixel sensors. In some implementations, the oxide layer 320 includes an oxide material such as a silicon oxide (SiOₓ). In some implementations, a silicon nitride (SiNₓ), a silicon carbide (SiCₓ), or a mixture thereof, such as a silicon carbon nitride (SiCN), a silicon oxynitride (SiON), or another type of dielectric material is used in place of the oxide layer 320.

A sidewall oxide layer 322 may be included over and/or the gate dielectric layer 314 on the frontside surface of the substrate 302. The sidewall oxide layer 322 may also be included on sidewalls of a portion of the gate electrode 310. The sidewall oxide layer 322 may include an oxide such as silicon oxide (SiOₓ) or another type of oxide material. A remote plasma oxide (RPO) layer 324 may be included over and/or on the sidewall oxide layer 322 over the frontside surface of the substrate 302. The remote plasma oxide layer 324 may also be included over the sidewall oxide layer 322 on the sidewalls of the portion of the gate electrode 310. A contact etch stop layer (CESL) 326 may be included over and/or on the remote plasma oxide layer 324 over the frontside surface of the substrate 302.

The vertical transfer gate 204 and the drain region 308 may be electrically connected to interconnects 328 and 330, respectively, with respective metallization layers 332 and 334 above the substrate 302. The interconnects 328 and 330, and the metallization layers 332 and 334, may be included in one or more dielectric layers 336. The interconnect 328 may be electrically connected with gate electrode 310 of the vertical transfer gate 204. In some implementations, the dielectric layer(s) 336 surround and/or encapsulate the interconnects 328 and 330, as well as the metallization layers 332 and 334. The dielectric layer(s) 336 may include an inter-metal dielectric (IMD) layer formed of an oxide material such as a silicon oxide (SiOₓ) (e.g., silicon dioxide (SiO₂)), a silicon nitride (SiNₓ), a silicon carbide (SiCₓ), a titanium nitride (TiNₓ), a tantalum nitride (TaNₓ), a hafnium oxide (HfOₓ), a tantalum oxide (TaOₓ), or an aluminum oxide (AlOₓ), or another type of dielectric material. The interconnects 328 and 330, as well as the metallization layers 332 and 334, may include one or more conductive materials, such as tungsten (W), cobalt (Co), ruthenium (Ru), copper (Cu), and/or another type of conductive material.

As further shown in FIG. 3A, the pixel sensor 202 may include one or more layers on the back side or a bottom side of the substrate 302. On the substrate 302 (e.g., on the bottom of the substrate 302), a p⁺ ion layer 338 may be included to increase photon-electron conversion. An antireflective coating (ARC) layer 340 may be included above and/or on the p⁺ ion layer 338. The ARC 340 may include a suitable material for reducing a reflection of incident light projected toward the photodiode 304. For example, the ARC 340 may include nitrogen-containing material.

A color filter layer 342 may be included above and/or on the ARC 340. In some implementations, the color filter layer 342 includes a visible light color filter configured to filter a particular wavelength or a particular wavelength range of visible light (e.g., red light, blue light, or green light). In some implementations, the color filter layer 342 includes a near infrared (NIR) filter (e.g., an NIR bandpass filter) configured to permit wavelengths associated with NIR light to pass through the color filter layer 342 and to block other wavelengths of light. In some implementations, the color filter layer 342 includes an NIR cut filter configured to block NIR light from passing through the color filter layer 342. In some implementations, the color filter layer 342 is omitted from the pixel sensor 202 to permit all wavelengths of light to pass through to the photodiode 304. In these examples, the pixel sensor 202 may be configured as a white pixel sensor.

A micro-lens layer 344 may be included above and/or on the color filter layer 342. The micro-lens layer 344 may include a micro-lens for the pixel sensor 202 configured to focus incident light toward the photodiode 304 and/or to reduce optical crosstalk between the pixel sensor 202 and one or more adjacent pixel sensors.

As shown in FIG. 3B, in operation of the pixel sensor 202, a photocurrent 346 is generated by photons of incident light absorbed in the photodiode 304. A current (or voltage) may be applied to the gate electrode 310 of the vertical transfer gate 204 from the metallization layer 332 through an interconnect 328. The current (or voltage) may energize the vertical transfer gate 204, which causes an electric field to form a conductive channel in the substrate 302 between the photodiode 304 and the drain extension region 306. The photocurrent 346 may flow through the conductive channel from the photodiode 304 to the drain extension region 306. The photocurrent 346 may flow from the drain extension region 306 to the drain region 308. The photocurrent 346 may be measured through the interconnect 330 at the metallization layer 334.

As indicated above, FIGS. 3A and 3B are provided as examples. Other examples may differ from what is described with regard to FIGS. 3A and 3B.

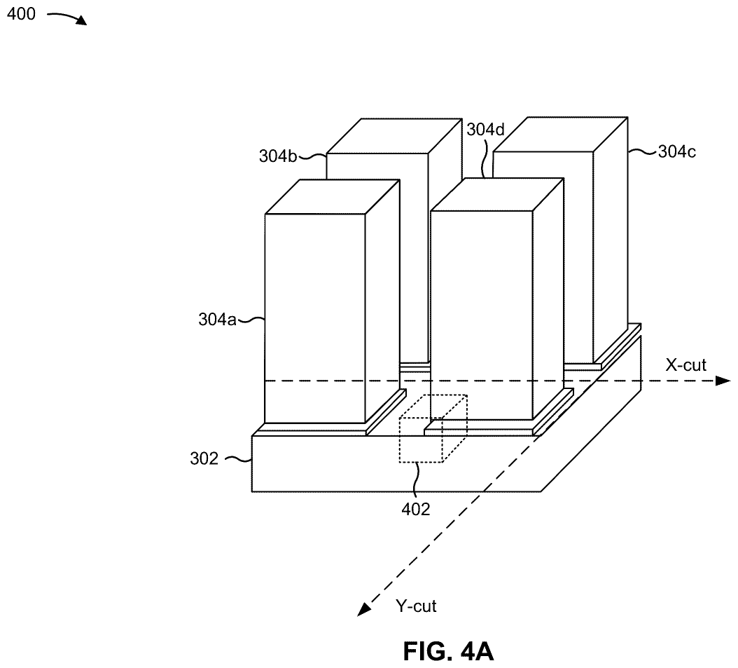

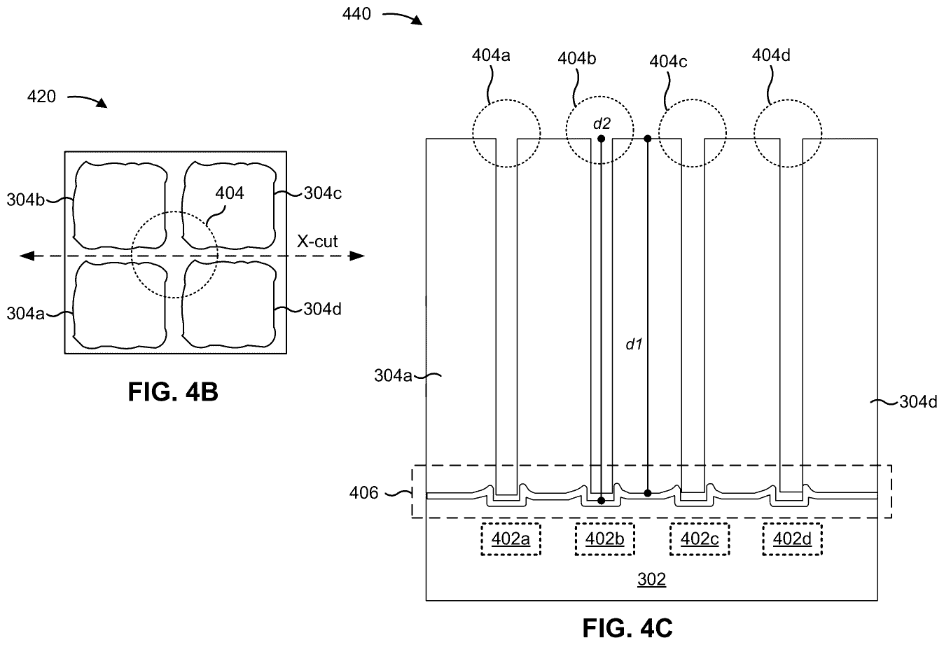

FIGS. 4A, 4B, and 4C are diagrams of example implementations 400, 420, and 440, respectively, of a trench for a DTI structure 208 of a pixel array 200 described herein. As shown in FIG. 4A, a plurality of photodiodes 304a, 304b, 304c, and 304d are formed over a substrate 302. The photodiodes 304a, 304b, 304c, and 304d may each be associated with, and/or included in, a pixel sensor 202. Lower in the substrate 302 is an FD region 402. For example, the FD region 402 may comprise at least a portion of a drain region 308 (e.g., as described in connection with FIGS. 3A and 3B). Although shown with four photodiodes and one FD region (e.g., for a 4T CMOS design), other implementations may include additional photodiodes (e.g., five photodiodes for a 5T CMOS design or six photodiodes for a 6T CMOS design) and/or additional FD regions.

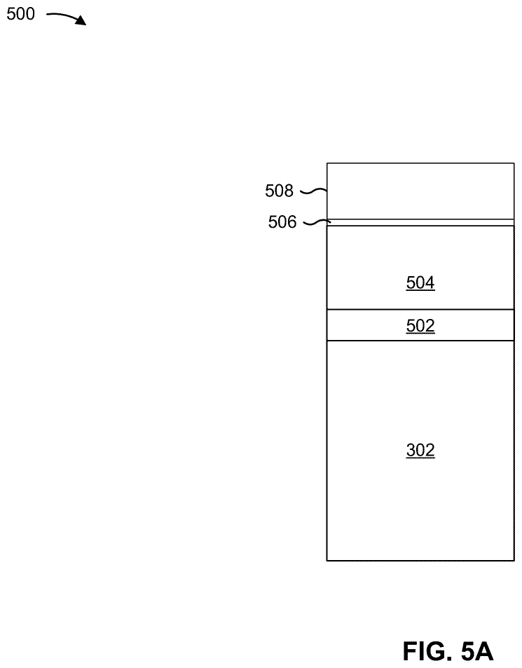

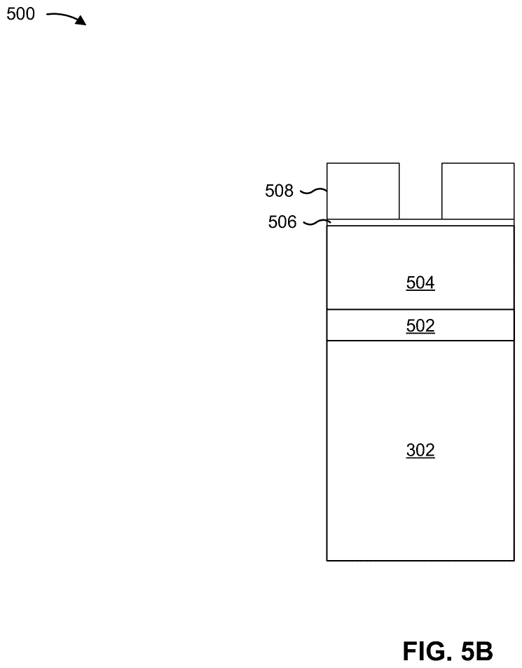

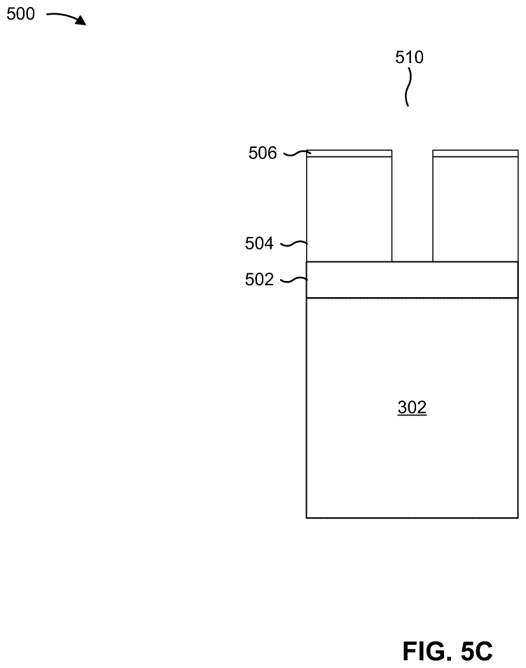

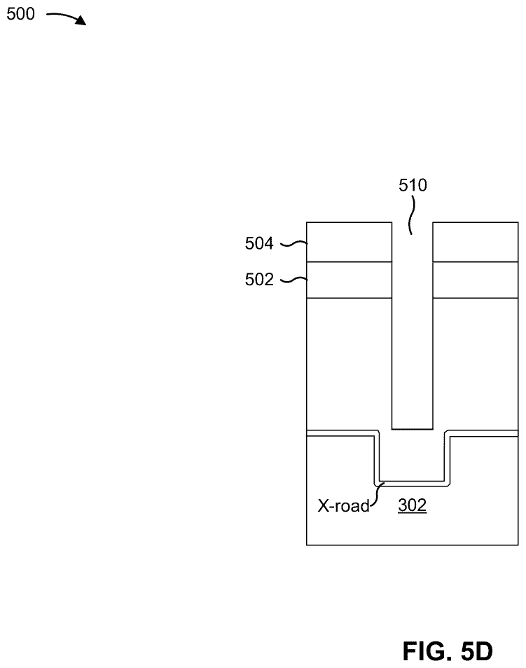

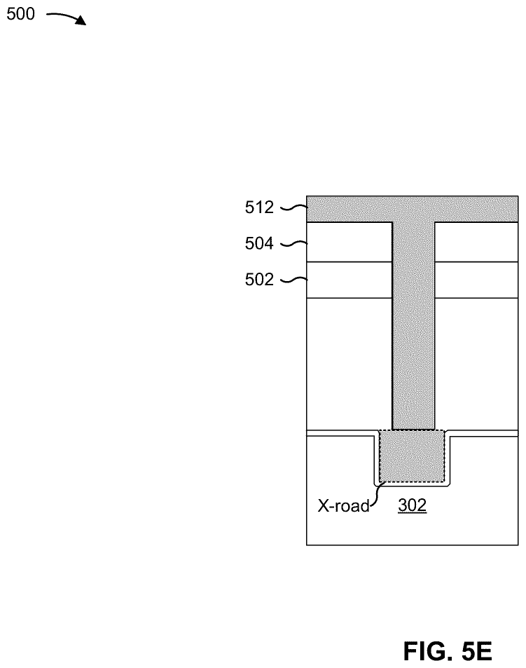

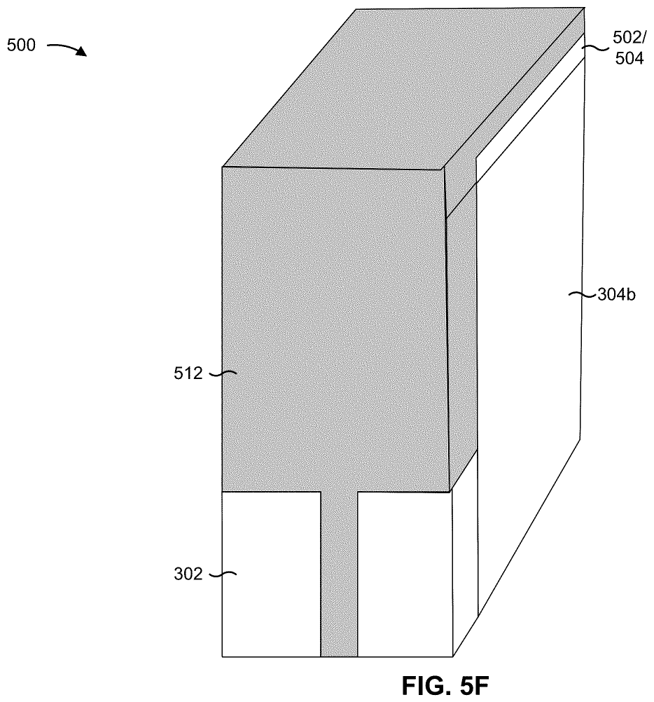

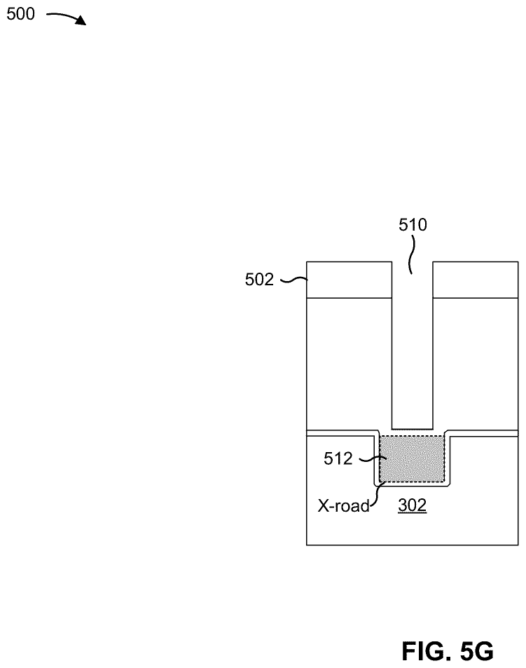

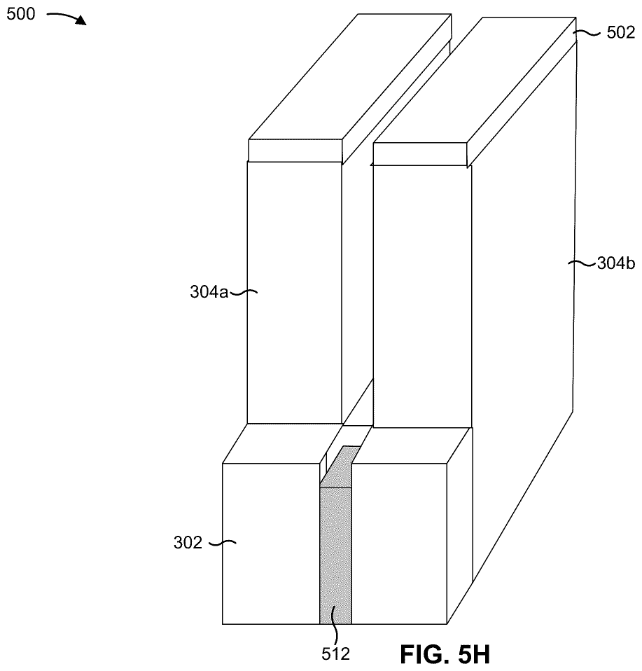

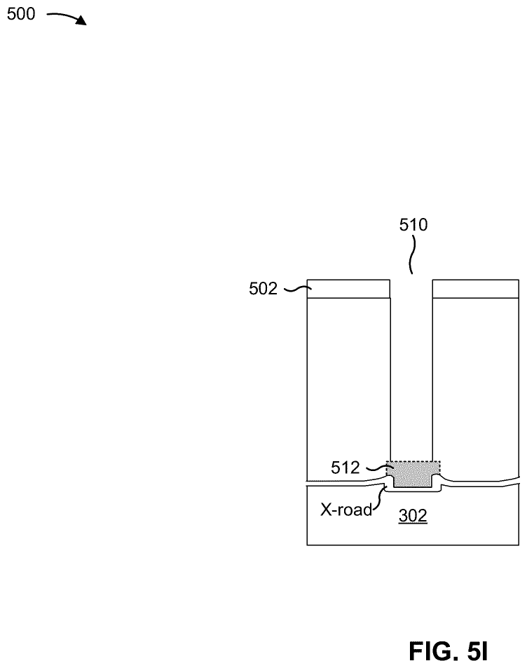

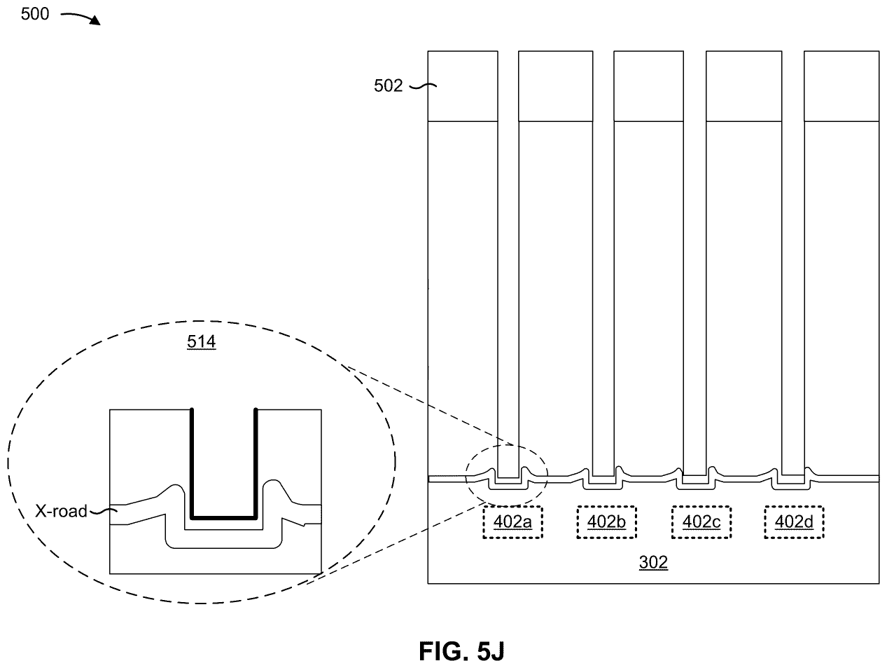

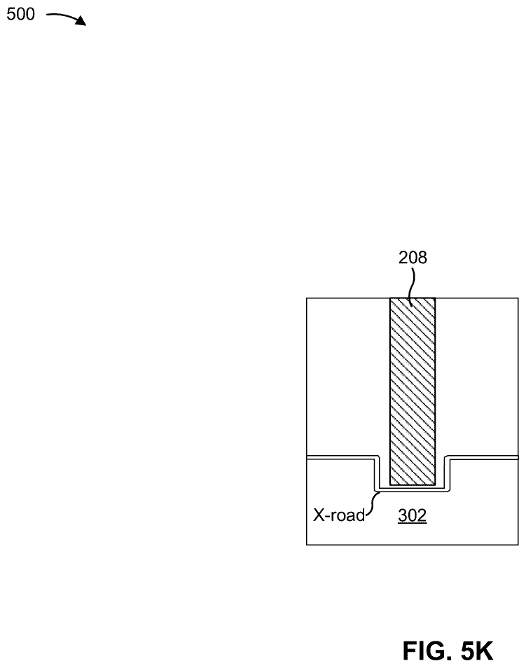

As further shown in FIG. 4A, a trench has been formed around and between the photodiodes 304a, 304b, 304c, and 304d in which a DTI structure will be formed. As described in connection with FIGS. 5A-5J, the trench may have been formed using a plurality of etching cycles. Accordingly, a plug (e.g., described in connection with FIGS. 5E-5I) may have protected the FD region 402 from being etched during formation of the trench.

The trench is both along an X-cut of the pixel array 200 and along a Y-cut of the pixel array 200. Accordingly, the trench is widest and deepest at an X-road of the pixel array 200. The X-road is a zone surrounding a location that is between the four photodiodes 304a, 304b, 304c, and 304d. In other words, the X-road is a zone above the FD region 402.

FIG. 4B shows a top-down view of the pixel array 200 of FIG. 4A. In FIG. 4B, the X-road is shown as zone 404. Accordingly, the trench in the zone 404 may have a width in a range from approximately 0.12 micrometers (μm) to approximately 0.4 μm. For example, the plug (e.g., as described in connection with FIGS. 5E-5I may have prevented the trench from having a width wider than 0.4 μm in the zone 404. By keeping the width no larger than 0.4 μm, the FD region 402 is protected from overetching during a subsequent etching cycle for the trench, which prevents electrical leakage and improves performance of the pixel array 200. Additionally, by having at least a width of 0.12 μm, the trench is large enough such that the DTI structure electrically insulates the photodiodes 304a, 304b, 304c, and 304d, which improves performance of the pixel array 200.

Additionally, the trench outside the zone 404 may have a width in a range from approximately 0.1 μm to approximately 0.2 μm. Outside the zone 404 may include a location of the DTI structure that is between two adjacent photodiodes of the photodiodes 304a, 304b, 304c, and 304d (e.g., along the X-cut or perpendicular to the X-cut but outside of the X-road). For example, the plug (e.g., as described in connection with FIGS. 5E-5I may have prevented the trench from having a width wider than 0.2 μm in the zone 404. By keeping the width no larger than 0.2 μm, the FD region 402 is protected from overetching during a subsequent etching cycle for the trench, which prevents electrical leakage and improves performance of the pixel array 200. Additionally, by having at least a width of 0.1 μm, the trench is large enough such that the DTI structure electrically insulates the photodiodes 304a, 304b, 304c, and 304d, which improves performance of the pixel array 200.

FIG. 4C shows a side view of the pixel array 200 of FIG. 4A along the X-cut combined with a view along a cut through photodiodes 304a and 304d. In FIG. 4C, the X-roads are shown as zones 404a, 404b, 404c, and 404d. The trench outside the zones 404a, 404b, 404c, and 404d may have a depth (e.g., represented by d1) in a range from approximately 2.0 μm to approximately 3.0 μm. Outside the zones 404a, 404b, 404c, and 404d may include a location of the DTI structure that is between two adjacent photodiodes the pixel array 200 (e.g., along the X-cut or perpendicular to the X-cut but outside of the X-road). For example, the plug (e.g., as described in connection with FIGS. 5E-5I may have prevented the trench from having a depth wider than 3.0 μm outside the zones 404a, 404b, 404c, and 404d. By keeping the depth no larger than 3.0 μm, FD regions 402a, 402b, 402c, and 402d are protected from overetching during a subsequent etching cycle for the trench, which prevents electrical leakage and improves performance of the pixel array 200. Additionally, by having at least a depth of 2.0 μm, the trench is large enough such that the DTI structure electrically insulates the photodiodes, which improves performance of the pixel array 200.

Additionally, the trench in the zones 404a, 404b, 404c, and 404d may have a depth (e.g., represented by d2) in a range from approximately 2.0 μm to approximately 3.5 μm. For example, the plug (e.g., as described in connection with FIGS. 5E-5I may have prevented the trench from having a depth wider than 3.5 μm in the zone 404. By keeping the depth no larger than 3.5 μm, the FD region 402 is protected from overetching during a subsequent etching cycle for the trench, which prevents electrical leakage and improves performance of the pixel array 200. Additionally, by having at least a depth of 2.0 μm, the trench is large enough such that the DTI structure electrically insulates the photodiodes 304a, 304b, 304c, and 304d, which improves performance of the pixel array 200.

As further shown in FIG. 4C, a region above the FD region 402 and adjacent to the photodiodes 304 may form a micro-topography region 406. The micro-topography region 406 may have a height, relative to the photodiodes, in a range from approximately 0.01 μm to approximately 0.2 μm. By keeping the height no larger than 0.2 μm, the micro-topography region 406 provides for more volume for the DTI structure, which increases how many photons are received at the photodiodes and thus improves performance of the pixel array 200. Additionally, by having at least a height of 0.01 μm, the photodiodes are not damaged during formation and etching of the plug and during etching of the trench, which improves performance of the pixel array 200.

As indicated above, FIGS. 4A-4C are provided as examples. Other examples may differ from what is described with regard to FIGS. 4A-4C.

FIGS. 5A-5K are diagrams of an example implementation 500 described herein. Example implementation 500 may be an example process for forming a DTI structure 208 of a pixel sensor 202 described herein, such as the pixel sensor 202 described in connection with FIGS. 3A and 3B. FIGS. 5A-5E and 5G-5J combine a side view along an X-cut combined with a view along a cut through photodiodes of the pixel sensor 202.

As shown in FIG. 5A, the example process for forming the DTI structure 208 may be performed in connection with a substrate 302. As described above, the substrate 302 may include a semiconductor die substrate, a semiconductor wafer, a stacked semiconductor wafer, or another type of substrate in which semiconductor pixels may be formed. For example, the substrate 302 may be formed of silicon (Si) (e.g., a silicon substrate), a material including silicon, a III-V compound semiconductor material such as gallium arsenide (GaAs), a silicon on insulator (SOI), or another type of semiconductor material that is capable of generating a charge from photons of incident light. In some implementations, the substrate 302 is formed of a doped material (e.g., a p-doped material or an n-doped material) such as a doped silicon. Additionally, the substrate 302 may have photodiodes formed therein above an FD region formed therein (not shown in FIG. 5A, which is along an X-cut, such that the photodiodes and the FD region are behind the substrate 302 as depicted in FIG. 5A).

As further shown in FIG. 5A, one or more masking layers (e.g., masking layer 502, blocking layer 504, and masking layer 506 in example implementation 500) may be formed over the substrate 302. For example, the deposition tool 102 may form the masking layer 502 over and/or on the frontside surface of the substrate 302, may form the blocking layer 504 over and/or on the masking layer 502, and may form the masking layer 506 over and/or on the blocking layer 504. In some implementations, the deposition tool 102 may form the masking layer(s) using a spin-coating technique, a CVD technique, a PVD technique, an ALD technique, and/or another deposition technique.

In some implementations, the masking layer 502 may be a hard masking layer and therefore may comprise a dielectric material (e.g., an oxide, a nitride, or an oxynitride, among other examples) and/or a silicon material. In some implementations, the masking layer 502 may be deposited to a thickness in a range from approximately 1.3 kiloangstroms (kA) to approximately 2.0 kA. For example, the deposition tool 102 may perform a deposition technique for an amount of time that satisfies a deposition threshold associated with forming the masking layer 502 to a thickness from approximately 1.3 kA to approximately 2.0 kA. By selecting a thickness of at least 1.3 kA, the masking layer 502 protects the photodiodes during DTI etching cycles. By selecting a thickness of no more than 2.0 kA, the masking layer 502 may be etched (e.g., as described in connection with FIG. 5K) without damaging the photodiodes.

The blocking layer 504 may be deposited to a thickness in a range from approximately 6.0 kA to approximately 8.0 kA. For example, the deposition tool 102 may perform a deposition technique for an amount of time that satisfies a deposition threshold associated with forming the blocking layer 504 to a thickness from approximately 6.0 kA to approximately 8.0 kA. By selecting a thickness of at least 6.0 kA, the blocking layer 504 protects the masking layer 502 during an initial DTI etch (e.g., as described in connection with FIGS. 5C-5D). By selecting a thickness of no more than 8.0 kA, the blocking layer 504 may be etched after deposition of a plug (e.g., as described in connection with FIGS. 5E-5G).

In some implementations, the masking layer 506 may be a hard masking layer and therefore may comprise a dielectric material (e.g., an oxide, a nitride, or an oxynitride, among other examples) and/or a silicon material. In some implementations, the masking layer 506 may be deposited to a thickness in a range from approximately 300 Angstroms (Å) to approximately 500 Å. For example, the deposition tool 102 may perform a deposition technique for an amount of time that satisfies a deposition threshold associated with forming the masking layer 506 to a thickness from approximately 300 Å to approximately 500 Å. By selecting a thickness of at least 300 Å, the blocking layer 504 is not fully etched during an initial DTI etch (e.g., as described in connection with FIGS. 5C-5D). By selecting a thickness of no more than 500 Å, the masking layer 506 may be removed during the initial DTI etch.

Alternatively, the masking layers 504 and 506 may comprise a combination of an organic layer and a coating over the organic layer. The deposition tool 102 may form the organic layer by CVD. The organic layer may comprise an aminophenyl fluorescein (APF), amorphous carbon, asterridinone (ARD), or a combination thereof. In some implementations, the organic layer may be deposited to a thickness in a range from approximately 4.0 kA to approximately 8.0 kA. For example, the deposition tool 102 may perform a deposition technique for an amount of time that satisfies a deposition threshold associated with forming the organic layer to a thickness from approximately 4.0 kA to approximately 8.0 kA. By selecting a thickness of at least 4.0 kA, the organic layer protects the FD region (not shown) during a subsequent DTI etch (e.g., as described in connection with FIGS. 5C and 5D). By selecting a thickness of no more than 8.0 kA, the organic layer may be etched, as described in connection with FIG. 5G, before formation of the DTI structure, as described in connection with FIG. 5K.

The deposition tool 102 may form the coating using a spin-coating technique, a CVD technique, a PVD technique, an ALD technique, and/or another deposition technique. The coating may comprise a silicon oxynitride. In some implementations, the coating may be deposited to a thickness in a range from approximately 0.3 kA to approximately 1.0 kA. For example, the deposition tool 102 may perform a deposition technique for an amount of time that satisfies a deposition threshold associated with forming the coating to a thickness from approximately 0.3 kA to approximately 1.0 kA. By selecting a thickness of at least 0.3 kA, the coating protects the FD region (not shown) during a subsequent DTI etch (e.g., as described in connection with FIG. 5C). By selecting a thickness of no more than 1.0 kA, the coating may be removed (e.g., as described in connection with FIG. 5D).

Although described with respect to three masking layers, other implementations may use fewer masking layers (e.g., with larger depths so as to protect the photodiodes during etching) or additional masking layers (e.g., with smaller depths to allow for etching the additional masking layers). As further shown in FIG. 5A, a photoresist layer 508 may be formed over the masking layer(s). For example, the deposition tool 102 may form the photoresist layer 508 over and/or on the frontside surface of the masking layer 506. In some implementations, the deposition tool 102 may form the photoresist layer 508 using a spin-coating technique, a CVD technique, a PVD technique, an ALD technique, and/or another deposition technique.

As shown in FIG. 5B, the exposure tool 104 may expose the photoresist layer 508 to a radiation source to form a pattern on the photoresist layer 508. For example, the pattern may corresponding to a trench to be formed for the DTI structure 208. The developer tool 106 may develop and remove portions of the photoresist layer 508 to expose the pattern.

As shown in FIG. 5C, the etch tool 108 may etch a portion of the masking layers 502, 504, and 506 to extend the pattern into the masking layers 502, 504, and 506. For example, the etch tool 108 may use a wet etch technique, a dry etch technique, a plasma-enhanced etch technique, and/or another type of etch technique to etch the portion of the masking layers 502, 504, and 506. Additionally, as further shown in FIG. 5C, the etch tool 108 may etch into a portion of the substrate 302 to form a trench 510 in the substrate 302. For example, the etch tool 108 may use a wet etch technique, a dry etch technique, a plasma-enhanced etch technique, and/or another type of etch technique to etch the portion of the substrate 302 to form the trench 510. The trench 510 may be adjacent to (or side-by-side with) the photodiodes (not shown in FIG. 5C, as explained above) and above the FD region (not shown in FIG. 5C as explained above). The trench 510 may surround the photodiodes so that the DTI structure 208 to be formed therein will surround the photodiodes, as described in connection with FIGS. 2 and 3A.

The depth of the trench 510 may have a second depth at the X-road that is in a range from approximately 140% to approximately 160% of a first depth of the trench 510 outside of the X-road. In other words, the depth of the trench 510 at the X-road is greater relative to a depth of the trench 510 outside of the X-road. (It is to be noted that the view in FIG. 5C is an elevation view of a cross-section of the trench 510, and the X-road is superimposed or in front of the first depth area of the trench 510 shown in FIG. 5C.) By selecting the second depth to be at least 140% of the first depth, the DTI structure 208 to be formed in the trench 510 will electrically insulate the photodiodes 304a, 304b, 304c, and 304d, which improves performance of the pixel sensor 202. By selecting the second depth to be no more than 160% of the first depth, the FD region is protected from overetching during a subsequent etching cycle for the trench, which prevents electrical leakage and improves performance of the pixel sensor 202.

In some implementations, the etch tool 108 may use a deep reactive ion etching (DRIE) to form the trench 510. For example, the etch tool 108 may perform an isotropic plasma etch (e.g., using a sulfur source, such as sulfur hexafluoride (SF₆)) in alternation with the deposition tool 102 forming a passivation layer to protect sidewalls of the trench 510 (e.g., where the passivation layer may comprise a polytetrafluoroethylene-based (PTFE-based) composition such that the deposition tool 102 uses an octafluorocyclobutane (C₄F₈) source). Alternatively, the etch tool 108 may use a non-DRIE etch. For example, the etch tool 108 may perform an isotropic plasma etch (e.g., using a sulfur source, such as sulfur hexafluoride (SF₆) or tetrafluoromethane (CF₄)) in combination with a polymer gas to protect sidewalls of the trench 510 (e.g., using an oxygen (O₂) gas or an octafluorocyclobutane (C₄F₈) gas).

As shown in FIG. 5D, a photoresist removal tool may remove the remaining portions of the photoresist layer 508 (e.g., using a chemical stripper, a plasma asher, and/or another technique) after the etch tool 108 etches the substrate 302 to form the trench 510. Additionally, the etch tool 108 may etch the masking layer 506 and a portion of the blocking layer 504. For example, the etch tool 108 may use a wet etch technique, a dry etch technique, a plasma-enhanced etch technique, and/or another type of etch technique to remove the masking layer 506 and the portion of the blocking layer 504.

As shown in FIG. 5E, the deposition tool 102 may deposit a self-aligned plug 512 (e.g., a carbon-based composition) in the trench 510 and over the blocking layer 504. In some implementations, the plug 512 may comprise a coating. The deposition tool 102 may form the coating using a spin-coating technique, a CVD technique, a PVD technique, an ALD technique, and/or another deposition technique. The coating may comprise acrylate or another type of organic compound.

Because the plug 512 is deposited as a blanket layer, the plug 512 is also deposited over the photodiodes (e.g., photodiode 304b), as shown in FIG. 5F. FIG. 5F is an angled view rather than a view along the X-cut. For example, the plug 512 may have a height, relative to the masking layer 504, in a range from approximately 0.1 μm to approximately 0.9 μm. By selecting a height of at least 0.1 μm, the plug 512 may be etched back (e.g., as described in connection with FIGS. 5G-5H) without damaging the photodiodes (e.g., photodiode 304b). By selecting a height of no more than 0.9 μm, the plug 512 may be etched back such that a remainder of the plug 512 is concentrated at the X-road (e.g., as depicted in FIGS. 5G-5H).

Additionally, because the plug 512 fill in the trench 510, the plug 512 may have a second depth at the X-road that is in a range from approximately 130% to approximately 150% of a first depth of the plug 512 outside of the X-road. By selecting the second depth to be at least 130% of the first depth, the plug 512 may be etched back such that a remainder of the plug 512 is concentrated at the X-road (e.g., as depicted in FIGS. 5G-5H). By selecting the second depth to be no more than 150% of the first depth, the trench 510 is formed deep enough during a subsequent etch cycle so that the DTI structure 208 to be formed therein insulates the photodiodes.

As shown in FIG. 5G, the etch tool 108 may perform an etch back operation after the deposition tool 102 forms the plug 512. The etch tool 108 may perform the etch back to remove a portion of the plug 512 such that a remainder of the plug is at the X-road (e.g., in a portion of the trench 510 that is located between four corners of a subset of the plurality of photodiodes). The etch tool 108 may perform the etch back using plasma ashing with oxygen (O₂), nitrogen (N₂), and/or another type of plasma. The etch tool 108 may remove the coating of the plug 512 such that only the organic layer of the plug 512 remains. Additionally, as further shown in FIG. 5G, the etch tool 108 may remove the blocking layer 504 and a portion of the masking layer 502.

Because the plug 512 is etched back, the portions of the plug 512 over the photodiodes (e.g., photodiodes 304a and 304b) are removed, as shown in FIG. 5H. FIG. 5H is an angled view rather than a view along the X-cut. Additionally, portions of the plug 512 over the substrate 302 that are outside the X-road may be removed, as shown in FIG. 5H. Accordingly, a remainder of the plug 512 may be concentrated at the X-road. The plug 512 may be referred to as a “self-aligned” plug in that the plug 512 may be used to complete a subsequent processing operation (e.g., a second etch operation to further increase the depth of the trench 510 in the non-X-road areas of the trench 510) without the use of additional photoresists and/or masking layers. Thus, the subsequent processing operation is self-aligned, or directed to process, the desired areas of the trench 510 by the plug 512.

As shown in FIG. 5I, the etch tool 108 may increase the depth the trench 510 with the plug 512 protecting the FD region during expansion of the trench 510. In other words, the etch tool 108 may etch the substrate 302 to increase the depth of the trench 510 in the non-X-road areas of the trench while the plug 512 protects the X-road of the trench 510 from further etching. This enables the depth in the non-X-road areas of the trench 510 to be increased without further increasing the depth of the trench 510 at the X-road. In some implementations, the etch tool 108 may use a DRIE to expand the trench 510. For example, the etch tool 108 may perform an isotropic plasma etch (e.g., using a sulfur source, such as sulfur hexafluoride (SF₆)) in alternation with the deposition tool 102 forming a passivation layer to protect sidewalls of the trench 510 (e.g., where the passivation layer may comprise a PTFE-based composition such that the deposition tool 102 uses an octafluorocyclobutane (C₄F₈) source). Alternatively, the etch tool 108 may use a non-DRIE etch. For example, the etch tool 108 may perform an isotropic plasma etch (e.g., using a sulfur source, such as sulfur hexafluoride (SF₆) or tetrafluoromethane (CF₄)) in combination with a polymer gas to protect sidewalls of the trench 510 (e.g., using an oxygen (O₂) gas or an octafluorocyclobutane (C₄F₈) gas).

As shown in FIG. 5J, the etch tool 108 may remove the plug 512 after expansion of the trench 510. The etch tool 108 may perform the etch back to remove a portion of the plug 512. The etch tool 108 may perform the etch back using plasma ashing with oxygen (O₂) and/or another type of plasma. As shown by inset 514, the FD region (e.g., FD region 402a) under the X-road was protected by the plug 512 during expansion of the trench 510 and was not damaged during removal of the plug 512. Furthermore, the plug 512 resulted in the trench 510 having the dimensions as described in connection with FIGS. 4A-4C.

In some implementations, trace organic material may remain in the trench 510 on the sidewalls and/or at the bottom surface, particularly at the X-road. In some implementations, the trench 510 may include trace amounts of an organic compound (from the organic layer of the plug 512) in combination with a silicon oxynitride (from the coating of the plug 512). As used herein, “trace amounts” refer to amounts present on less than 50% of the surface area of the trench 510.

Accordingly, as shown in FIG. 5K, the etch tool 108 may remove a remainder of the masking layer 502. The etch tool 108 may remove the masking layer 502 using hydrochloric acid (HCl) and/or another etchant to dissolve the masking layer 502. For example, the etch tool 108 may perform a wet etch technique for an amount of time that satisfies a removal threshold associated with removing the masking layer 502 but not damaging the photodiodes.

In some implementations, the trench 510 may be lined with one or more layers (e.g., layer 318a and/or layer 318b, as described herein). The deposition tool 102 may form the layer(s) by conformal deposition such that the layer(s) are formed as thin films that conform to the shape and/or profile of the sidewalls and bottom surface of the trench 510.

As further shown in FIG. 5K, the trench 510 may be filled with an oxide material to form the DTI structure 208 (e.g., from an oxide layer 320, as described herein). The deposition tool 102 may form the DTI structure using a CVD technique, a PVD technique, an ALD technique, or another type of deposition technique. The planarization tool 110 may planarize the DTI structure 208 after the oxide layer is deposited in the trench 510 such that a top surface of the DTI structure 208 and a backside surface of the substrate 302 are approximately a same height.

As indicated above, FIGS. 5A-5K are provided as an example. Other examples may differ from what is described with regard to FIGS. 5A-5K

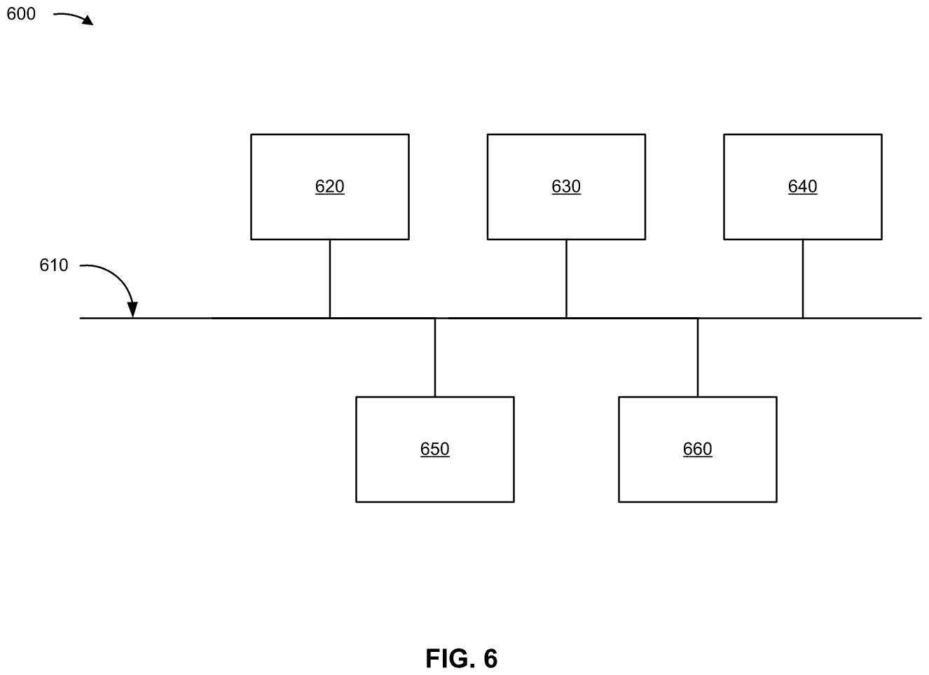

FIG. 6 is a diagram of example components of a device 600 described herein. In some implementations, one or more of the semiconductor processing tools 102-116 and/or the wafer/die transport tool 118 may include one or more devices 600 and/or one or more components of device 600. As shown in FIG. 6, device 600 may include a bus 610, a processor 620, a memory 630, an input component 640, an output component 650, and a communication component 660.

Bus 610 may include one or more components that enable wired and/or wireless communication among the components of device 600. Bus 610 may couple together two or more components of FIG. 6, such as via operative coupling, communicative coupling, electronic coupling, and/or electric coupling. Processor 620 may include a central processing unit, a graphics processing unit, a microprocessor, a controller, a microcontroller, a digital signal processor, a field-programmable gate array, an application-specific integrated circuit, and/or another type of processing component. Processor 620 is implemented in hardware, firmware, or a combination of hardware and software. In some implementations, processor 620 may include one or more processors capable of being programmed to perform one or more operations or processes described elsewhere herein.

Memory 630 may include volatile and/or nonvolatile memory. For example, memory 630 may include random access memory (RAM), read only memory (ROM), a hard disk drive, and/or another type of memory (e.g., a flash memory, a magnetic memory, and/or an optical memory). Memory 630 may include internal memory (e.g., RAM, ROM, or a hard disk drive) and/or removable memory (e.g., removable via a universal serial bus connection). Memory 630 may be a non-transitory computer-readable medium. Memory 630 stores information, instructions, and/or software (e.g., one or more software applications) related to the operation of device 600. In some implementations, memory 630 may include one or more memories that are coupled to one or more processors (e.g., processor 620), such as via bus 610.

Input component 640 enables device 600 to receive input, such as user input and/or sensed input. For example, input component 640 may include a touch screen, a keyboard, a keypad, a mouse, a button, a microphone, a switch, a sensor, a global positioning system sensor, an accelerometer, a gyroscope, and/or an actuator. Output component 650 enables device 600 to provide output, such as via a display, a speaker, and/or a light-emitting diode. Communication component 660 enables device 600 to communicate with other devices via a wired connection and/or a wireless connection. For example, communication component 660 may include a receiver, a transmitter, a transceiver, a modem, a network interface card, and/or an antenna.

Device 600 may perform one or more operations or processes described herein. For example, a non-transitory computer-readable medium (e.g., memory 630) may store a set of instructions (e.g., one or more instructions or code) for execution by processor 620. Processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry is used instead of or in combination with the instructions to perform one or more operations or processes described herein. Additionally, or alternatively, processor 620 may be configured to perform one or more operations or processes described herein. Thus, implementations described herein are not limited to any specific combination of hardware circuitry and software.

The number and arrangement of components shown in FIG. 6 are provided as an example. Device 600 may include additional components, fewer components, different components, or differently arranged components than those shown in FIG. 6. Additionally, or alternatively, a set of components (e.g., one or more components) of device 600 may perform one or more functions described as being performed by another set of components of device 600.

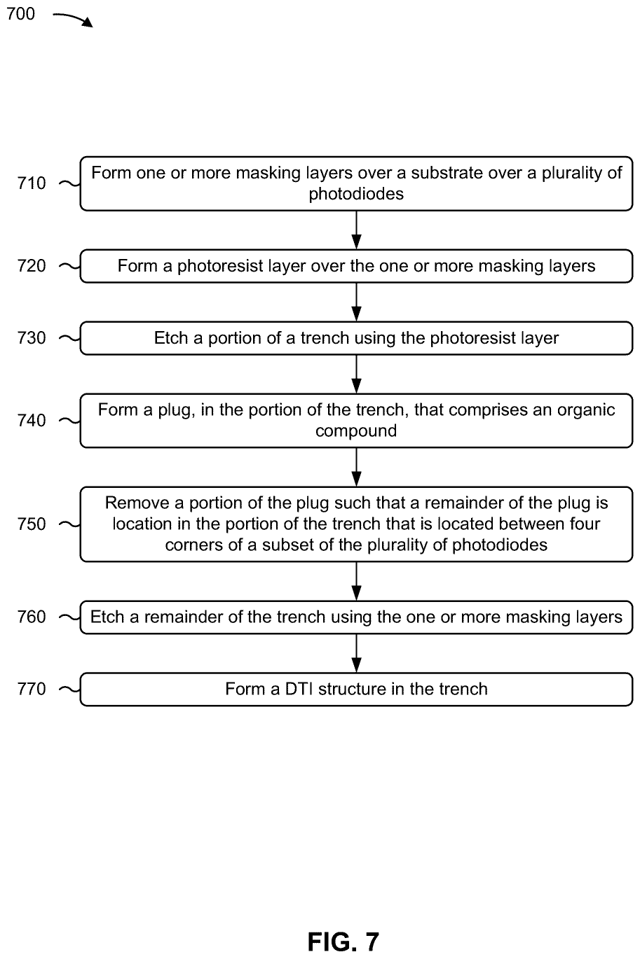

FIG. 7 is a flowchart of an example process 700 associated with forming pixel sensor isolation structures. In some implementations, one or more process blocks of FIG. 7 are performed by one or more semiconductor processing tools (e.g., one or more of the semiconductor processing tools 102-116). Additionally, or alternatively, one or more process blocks of FIG. 7 may be performed by one or more components of device 600, such as processor 620, memory 630, input component 640, output component 650, and/or communication component 660.

As shown in FIG. 7, process 700 may include forming one or more masking layers over a substrate over a plurality of photodiodes (block 710). For example, one or more of the semiconductor processing tools 102-116 may form one or more masking layers (layer 502, layer 504, and/or layer 506) over a substrate 302 over a plurality of photodiodes (photodiodes 304a, 304b, 304c, and/or 304d), as described herein.

As further shown in FIG. 7, process 700 may include forming a photoresist layer over the one or more masking layers (block 720). For example, one or more of the semiconductor processing tools 102-116 may form a photoresist layer 508 over the one or more masking layers 502, 504, and/or 506, as described herein.

As further shown in FIG. 7, process 700 may include etching a portion of a trench using the photoresist layer (block 730). For example, one or more of the semiconductor processing tools 102-116 may etch a portion of a trench 510 using the photoresist layer 508, as described herein.

As further shown in FIG. 7, process 700 may include forming a plug, in the portion of the trench, that comprises an organic compound (block 740). For example, one or more of the semiconductor processing tools 102-116 may form a plug 512, in the portion of the trench 510, that comprises an organic compound, as described herein.

As further shown in FIG. 7, process 700 may include removing a portion of the plug such that a remainder of the plug is in the portion of the trench that is located between four corners of a subset of the plurality of photodiodes (block 750). For example, one or more of the semiconductor processing tools 102-116 may remove a portion of the plug 512 such that a remainder of the plug 512 is in the portion of the trench 510 that is located between four corners of a subset of the plurality of photodiodes 304a, 304b, 304c, and/or 304d, as described herein.

As further shown in FIG. 7, process 700 may include etching a remainder of the trench using the one or more masking layers (block 760). For example, one or more of the semiconductor processing tools 102-116 may etch a remainder of the trench using the one or more masking layers 502, 504, and/or 506, as described herein.

As further shown in FIG. 7, process 700 may include forming a deep trench isolation structure in the trench (block 770). For example, one or more of the semiconductor processing tools 102-116 may form a DTI structure 208 in the trench 510, as described herein.

Process 700 may include additional implementations, such as any single implementation or any combination of implementations described below and/or in connection with one or more other processes described elsewhere herein.

In a first implementation, at least a portion of the plug 512 is lower in the substrate 302 than the plurality of photodiodes 304a, 304b, 304c, and/or 304d.

In a second implementation, alone or in combination with the first implementation, the remainder of the plug 512 protects an FD region 402 from etching during etching of the remainder of the trench 510.

In a third implementation, alone or in combination with one or more of the first and second implementations, etching the portion of the trench 510 includes a DRIE.

In a fourth implementation, alone or in combination with one or more of the first through third implementations, removing the portion of the plug 512 includes a fluorine etch.

In a fifth implementation, alone or in combination with one or more of the first through fourth implementations, removing the portion of the plug 512 uses oxygen or nitrogen.

In a sixth implementation, alone or in combination with one or more of the first through fifth implementations, process 700 includes removing a hard mask layer 502 using a wet etch process after forming the remainder of the trench 510.

In a seventh implementation, alone or in combination with one or more of the first through sixth implementations, the hard mask layer 510 has a thickness in a range from approximately 1.3 kA to approximately 2.0 kA.

In an eighth implementation, alone or in combination with one or more of the first through seventh implementations, process 700 includes removing a remainder of the plug 512 using an oxygen plasma after forming the remainder of the trench 510.

In a ninth implementation, alone or in combination with one or more of the first through eighth implementations, forming the plug 512 includes forming a coating.

In a tenth implementation, alone or in combination with one or more of the first through ninth implementations, process 700 includes forming a masking layer 504/506 that comprises a combination of an organic layer 504 and a coating 506, where the organic layer 504 includes an APF, amorphous carbon, ARD, or a combination thereof, and the masking layer 504/506 is reduced during the first etch process and is removed during the second etch process.

In an eleventh implementation, alone or in combination with one or more of the first through tenth implementations, the coating includes a silicon oxynitride.

In a twelfth implementation, alone or in combination with one or more of the first through eleventh implementations, the organic layer has a thickness in a range from approximately 4.0 kA to approximately 8.0 kA.

In a thirteenth implementation, alone or in combination with one or more of the first through twelfth implementations, the coating has a thickness in a range from approximately 0.3 kA to approximately 1.0 kA.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a self-aligned plug may be formed between DTI etching cycles. Accordingly, etch depth in areas of a pixel sensor with large CDs (e.g., at an X-road) is reduced, which prevents trench loading. As a result, an FD region, associated with photodiodes of the pixel sensor, is not damaged during the DTI etching cycles. Reduced chances of damage to the FD region improves performance of the pixel sensor and prevents electrical shorts and failures, which increases yield and conserves time and raw materials used in forming the pixel sensor.

As described in greater detail above, some implementations described herein provide a semiconductor structure. The semiconductor structure includes a plurality of photodiodes. The semiconductor structure includes a floating diffusion region associated with the plurality of photodiodes. The semiconductor structure includes a deep trench isolation (DTI) structure electrically isolating the plurality of photodiodes and formed above the floating diffusion region. The DTI structure has a micro-topography region with a height, relative to the plurality of photodiodes, in a range from approximately 0.01 micrometers (μm) to approximately 0.2 μm.

As described in greater detail above, some implementations described herein provide a method. The method includes performing a first etch process to form a portion of a trench, for a deep trench isolation (DTI) structure, between a plurality of photodiodes. The method includes forming a plug in the portion of the trench, where the plug includes an organic compound. The method includes performing a second etch process to remove a portion of the plug. The method includes performing a third etch process to form a remainder of the trench for the DTI structure.

As described in greater detail above, some implementations described herein provide a method. The method includes forming one or more masking layers over a substrate over a plurality of photodiodes. The method includes forming a photoresist layer over the one or more masking layers. The method includes etching a portion of a trench using the photoresist layer. The method includes forming a plug in the portion of the trench, where the plug includes an organic compound. The method includes removing a portion of the plug, where a remainder of the plug is in the portion of the trench that is located between four corners of a subset of the plurality of photodiodes. The method includes etching a remainder of the trench using the one or more masking layers. The method includes forming a deep trench isolation structure in the trench.

As used herein, “satisfying a threshold” may, depending on the context, refer to a value being greater than the threshold, greater than or equal to the threshold, less than the threshold, less than or equal to the threshold, equal to the threshold, not equal to the threshold, or the like. The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of photodiodes;
a floating diffusion region associated with the plurality of photodiodes; and
a deep trench isolation (DTI) structure electrically isolating the plurality of photodiodes and formed above the floating diffusion region,
wherein the DTI structure has a micro-topography region with a height, relative to the plurality of photodiodes, in a range from approximately 0.01 micrometers (μm) to approximately 0.2 μm.

2. The semiconductor structure of claim 1, wherein the DTI structure has a first width in a range from approximately 0.1 μm to approximately 0.2 μm and has a first depth in a range from approximately 2.0 μm to approximately 3.0 μm.

3. The semiconductor structure of claim 2, wherein the DTI structure has the first width and the first depth at a location of the DTI structure that is between two adjacent photodiodes of the plurality of photodiodes.

4. The semiconductor structure of claim 2, wherein the DTI structure has a second width in a range from approximately 0.12 μm to approximately 0.4 μm and has a second depth in a range from approximately 2.0 μm to approximately 3.5 μm.

5. The semiconductor structure of claim 4, wherein the DTI structure has the second width and the second depth at a location of the DTI structure that is between four of the plurality of photodiodes.

6. A method, comprising:
performing a first etch process to form a portion of a trench, for a deep trench isolation (DTI) structure, between a plurality of photodiodes;
forming a plug in the portion of the trench, wherein the plug comprises an organic compound;
performing a second etch process to remove a portion of the plug; and
performing a third etch process to form a remainder of the trench for the DTI structure.

7. The method of claim 6, wherein the first etch process comprises a deep reactive ion etching (DRIE).

8. The method of claim 6, wherein the second etch process comprises a fluorine etch.

9. The method of claim 6, wherein the second etch process uses oxygen or nitrogen.

10. The method of claim 6, further comprising:
removing a hard mask layer using a wet etch process after forming the remainder of the trench.

11. The method of claim 10, wherein the hard mask layer has a thickness in a range from approximately 1.3 kiloangstroms (kA) to approximately 2.0 kA.

12. The method of claim 6, further comprising:
removing a remainder of the plug using an oxygen plasma after forming the remainder of the trench.

13. The method of claim 6, wherein forming the plug comprises:
forming a coating.

14. The method of claim 6, further comprising:
forming a masking layer that comprises a combination of an organic layer and a coating,
wherein the organic layer comprises an aminophenyl fluorescein (APF), amorphous carbon, asterridinone (ARD), or a combination thereof,
wherein the masking layer is reduced during the first etch process and is removed during the second etch process.

15. The method of claim 14, wherein the coating comprises a silicon oxynitride.

16. The method of claim 14, wherein the organic layer has a thickness in a range from approximately 4.0 kiloangstroms (kA) to approximately 8.0 kA.

17. The method of claim 14, wherein the coating has a thickness in a range from approximately 0.3 kiloangstroms (kA) to approximately 1.0 kA.

18. A method, comprising:
forming one or more masking layers over a substrate over a plurality of photodiodes;
forming a photoresist layer over the one or more masking layers;
etching a portion of a trench using the photoresist layer;
forming a plug in the portion of the trench, wherein the plug comprises an organic compound;
removing a portion of the plug, wherein a remainder of the plug is in the portion of the trench that is located between four corners of a subset of the plurality of photodiodes;
etching a remainder of the trench using the one or more masking layers; and
forming a deep trench isolation structure in the trench.

19. The method of claim 18, wherein at least a portion of the plug is lower in the substrate than the plurality of photodiodes.

20. The method of claim 18, wherein the remainder of the plug protects a floating diffusion region from etching during etching of the remainder of the trench.
